(19) United States
(12) Patent Application Publication
(10) Pub. No.: US 2021/0335733 A1
(43) Pub. Date: Oct. 28, 2021

(54) ELECTRONIC DEVICE MODULE AND METHOD OF MANUFACTURING ELECTRONIC DEVICE MODULE

(71) Applicant: Samsung Electro-Mechanics Co., Ltd., Suwon-si (KR)

(72) Inventors: Seok Yoon HONG, Suwon-si (KR); Han Su PARK, Suwon-si (KR); Nam Il SEO, Suwon-si (KR)

(73) Assignee: Samsung Electro-Mechanics Co., Ltd., Suwon-si (KR)

(21) Appl. No.: 16/994,849

(22) Filed: Aug. 17, 2020

(30) Foreign Application Priority Data
Apr. 24, 2020 (KR) 10-2020-0050093

(51) Int. Cl. H01L 23/60; H01L 23/10; H01L 23/66; H05K 9/00; H01L 21/50

(52) U.S. Cl. CPC H01L 23/60; H01L 23/10; H01L 21/50; H05K 9/0022; H01L 23/66

(57) ABSTRACT

An electronic device module includes: a substrate; at least one electronic device mounted on a first surface of the substrate; a shielding wall mounted on the first surface of the substrate; a sealing portion disposed on the first surface of the substrate such that the at least one electronic device and the shielding wall are embedded in the sealing portion; and a shielding layer disposed on one surface of the sealing portion. At least a portion of the sealing portion is disposed externally of the shielding wall. The shielding wall and the shielding layer are formed of different materials.

### CROSS-REFERENCE TO RELATED APPLICATIONS

This application claims benefit under 35 U.S.C. § 119(a) of Korean Patent Application No. 10-2020-0050093 filed on Apr. 24, 2020 in the Korean Intellectual Property Office, the entire disclosure of which is incorporated herein by reference for all purposes.

### BACKGROUND

### 1. Field

The following description relates to an electronic device module that may effectively shield electromagnetic waves, and a method of manufacturing an electronic device module.

### 2. Description of Related Art

There has been increased demand for portable electronic products in the electronic product market. To meet such demand, electronic devices mounted in portable electronic products have been required to have a reduced size and weight.

To reduce the size and weight of such electronic devices, a technique of reducing an individual size of a mounting component has been implemented. Additionally, a system-on-chip (SOC) technique for configuring a plurality of individual devices on a single chip or a system-in-package (SIP) technique for integrating a plurality of individual devices as a single package have been implemented.

Particularly, a high frequency electronic device module that treats or uses a high frequency signal, such as a communications module or a network module, has been required to have various electromagnetic shielding structures to have a reduced size and to implement excellent shielding properties against electromagnetic interference (EMI).

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, an electronic device module includes: a substrate; at least one electronic device mounted on a first surface of the substrate; a shielding wall mounted on the first surface of the substrate; a sealing portion disposed on the first surface of the substrate such that the at least one electronic device and the shielding wall are embedded in the sealing portion; and a shielding layer disposed on one surface of the sealing portion. At least a portion of the sealing portion is disposed externally of the shielding wall. The shielding wall and the shielding layer are formed of different materials.

The shielding wall may be disposed to surround the at least one electronic device, and at least a portion of an end of the shielding wall may be electrically connected to the shielding layer.

The electronic device module may further include a shielding barrier wall disposed in an internal region inside of the shielding wall, and disposed between electronic devices among the at least one electronic device.

The sealing portion may include an internal sealing portion disposed in an internal space inside of the shielding wall, and an external sealing portion disposed on an external side of the shielding wall.

At least a portion of one surface of the external sealing portion may be exposed externally of the shielding layer.

At least a portion of the external sealing portion may have a thickness less than a thickness of the internal sealing portion.

The electronic device module may further include at least one communication device disposed in the external sealing portion.

The shielding wall may be formed of a polymer material containing conductive filler, and the shielding layer may be formed of a metal material.

An interfacial surface between the shielding wall and the shielding layer may be coplanar with an interfacial surface between the sealing portion and the shielding layer.

An upper surface of the shielding wall may include a groove in contact with the shielding layer.

The electronic device module may further include: an antenna disposed on a second surface of the substrate.

One surface of the sealing portion may include a chamfer portion chamfered along an edge.

A portion of the shielding layer disposed on the chamfer portion may have a thickness decreasing toward the edge.

In another general aspect, a method of manufacturing an electronic device module includes: forming a sealing portion embedding at least one electronic device on a substrate; forming a trench by partially removing the sealing portion; forming a shielding wall by filling the trench with a conductive member; and forming a shielding layer on an upper surface of the sealing portion. The shielding wall is not exposed externally of the sealing portion. The shielding wall is formed of a material different from a material of the shielding layer.

The method may further include forming a groove on an end of the shielding wall after the forming of the shielding wall.

The sealing portion may include an internal sealing portion disposed in an internal space formed inside of the shielding wall and an external sealing portion disposed on an external side of the shielding wall.

The at least one electronic device may be disposed in the internal sealing portion.

At least a portion of the external sealing portion may have a thickness less than a thickness of the internal sealing portion. An antenna device may be disposed in the external sealing portion or at an interface between the substrate and the external sealing portion.

Other features and aspects will be apparent from the following detailed description, the drawings, and the claims.

### BRIEF DESCRIPTION OF DRAWINGS

FIG. 1 is a perspective diagram illustrating an electronic device module, according to an embodiment.

FIG. 2 is a cross-sectional diagram along line I-I′ in FIG. 1.

FIGS. 3 to 8 are diagrams illustrating a method of manufacturing the electronic device module illustrated in FIG. 1, according to an embodiment.

FIG. 9 is a cross-sectional diagram illustrating an electronic device module, according to an embodiment.

FIG. 10 is a cross-sectional diagram illustrating a method of manufacturing the electronic device module illustrated in FIG. 9, according to an embodiment.

FIGS. 11 to 15 are cross-sectional diagrams illustrating electronic device modules, according to embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

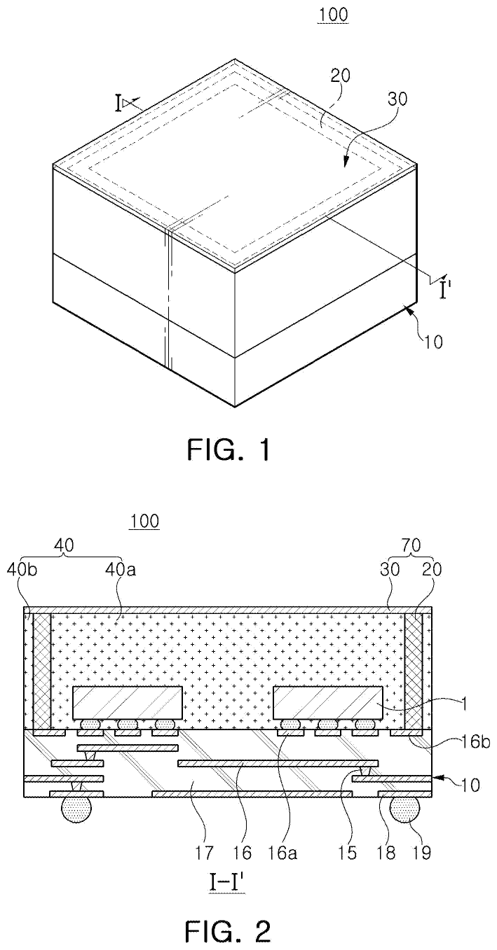

FIG. 1 is a perspective diagram illustrating an electronic device module 100, according to an embodiment. FIG. 2 is a cross-sectional diagram along line I-I′ in FIG. 1.

Referring to FIGS. 1 and 2, the electronic device module 100 may include, for example, a substrate 10, one or more electronic devices 1, a sealing portion 40, and a shielding portion 70.

The substrate 10 may be a multilayer substrate formed by alternately stacking a plurality of insulating layers 17 and a plurality of wiring layers 16. However, as another example, the substrate 10 may be configured as a dual-sided substrate in which the wiring layer 16 is formed on two opposite surfaces of the insulating layer 17. For example, the substrate 10 may be any one of various generally known types of substrates (e.g., a printed circuit board, a flexible substrate, a ceramic substrate, a glass substrate, or the like).

The insulating layer 17 may not be limited to any particular material. For example, an insulating material such as an thermosetting resin such as an epoxy resin, a thermoplastic resin such as a polyimide resin, an insulating material in which the thermosetting resin or the thermoplastic resin is impregnated in a core material such as an inorganic filler with a glass fiber, such as prepreg, Ajinomoto build-up film (ABF), FR-4, bismaleimide triazine (BT), or the like, may be used to form the insulating layer 17.

The wiring layer 16 may be electrically connected to the electronic device 1, and may also be electrically connected to the shielding portion 70.

A conductive material such as copper (Cu), aluminum (Al), silver (Ag), tin (Sn), gold (Au), nickel (Ni), lead (Pb), titanium (Ti), or alloys of copper (Cu), aluminum (Al), silver (Ag), tin (Sn), gold (Au), nickel (Ni), lead (Pb), or titanium (Ti) may be used as a material of the wiring layer 16.

Interlayer connection conductors 15 connecting the stacked wiring layers 16 to each other may be disposed in the insulating layer 17.

An insulating protective layer may be disposed on a surface of the substrate 10. The insulating protective layer may be formed of a solder resist, and may be configured to cover the wiring layers 16 and the insulating layers 17 on an upper surface and a lower surface of outermost insulating layers 17, respectively. Accordingly, the substrate 10 may include an outermost wiring layer 16 disposed on an upper surface or a lower surface of an outermost insulating layer 17.

The substrate 10 may include a first surface and a second surface opposing the first surface. The first surface may be a surface on which the one or more electronic devices 1 are mounted, and the second surface may be a surface facing a main substrate when the electronic device module 100 is mounted on a main substrate.

Electrodes 16a configured for mounting the electronic device 1 and at least one ground electrode 16b connected to the shielding wall may be disposed on the first surface of the substrate 10.

Connection electrodes 18 on which a connection terminal 19 such as a solder ball may be disposed on the second surface of the substrate 10. Accordingly, the electronic device module 100 may be electrically connected to an external structure or device through the connection electrodes 18 and the connection terminals 19.

The electronic device 1 may be mounted on one surface of the substrate 10. The electronic device 1 may include various devices such as an active device or a passive device, and any devices or components mountable on the substrate 10 may be implemented as the electronic device 1.

Also, the electronic device 1 may include a device which may emit electromagnetic waves or may need to be protected from electromagnetic waves flowing into the device while operating.

The sealing portion 40 may be disposed on the first surface of the substrate 10 and may seal the electronic device 1. The sealing portion 40 may safely protect the electronic device 1 from external impact by fastening the electronic device 1 by surrounding the electronic device 1 at the external sides of the electronic device 1.

The sealing portion 40 may be formed of an insulating material. For example, the sealing portion 40 may be formed of a resin material such as an epoxy molding compound (EMC), but is not limited to EMC. Also, the sealing portion 40 may include an internal sealing portion 40a and an external sealing portion 40b.

The internal sealing portion 40a may be disposed in an internal space disposed inside of a shielding wall 20, and may seal the one or more electronic devices 1.

In the sealing portion 40, the external sealing portion 40b may be disposed on an external surface of the shielding wall 20.

The internal sealing portion 40a and the external sealing portion 40b may not be connected to each other and may be completely separated by the shielding wall 20 and a shielding layer 30. However, the disclosure is not limited to the aforementioned configuration. As another example, the internal sealing portion 40a may be partially connected to the external sealing portion 40b.

The shielding portion 70 may shield electromagnetic waves flowing to the electronic device 1 or emitted from the electronic device 1.

The shielding portion 70 may include the shielding wall 20 and the shielding layer 30.

The shielding wall 20 may be disposed inside of the external sealing portion 40b and may be disposed side by side with a side surface of a surface of the sealing portion 40. Accordingly, the shielding wall 20 may be spaced apart from the side surface of the sealing portion 40 by a certain distance and may not be exposed externally of the sealing portion 40, and may be disposed to surround the internal sealing portion 40a. That is, the shielding wall 20 may be disposed between the internal sealing portion 40a and the external sealing portion 40b.

The shielding wall 20 may be electrically/physically connected to the ground electrode 16b of the substrate 10. For example, the shielding wall 20 may be disposed on the ground electrode 16b.

An upper end of the shielding wall 20 may be disposed on a same plane as an upper surface of the sealing portion 40. For example, an interfacial surface between the shielding wall 20 and the shielding layer 30 may be disposed on a same plane as an interfacial surface between the sealing portion 40 and the shielding layer 30. The configuration above may be implemented by performing a grinding method in a manufacturing method.

A lower end of the shielding wall 20 may be adhered to the ground electrode 16b of the substrate. An entire lower end of the shielding wall 20 may be adhered to the ground electrode 16b. Alternatively, the lower end of the shielding wall 20 may be only partially adhered to the ground electrode 16b.

The shielding wall 20 may be formed of a conductive material such as a metal or a polymer material containing conductive filler. For example, the shielding wall 20 may be formed of, but is not limited to, a conductive paste including conductive filler.

The shielding layer 30 may be formed along one surface (e.g., an upper surface illustrated in FIG. 2) of the surface of the sealing portion 40. The shielding layer 30 may be formed of a conductive material such as a metal material (e.g., copper (Cu), silver (Ag), gold (Au), nickel (Ni), platinum (Pt), palladium (Pd), or an alloy including any one or any combination of any two or more of Cu, Ag, Au, Ni, Pt, and Pd), and may be electrically connected to the ground electrode 16b of the substrate 10.

The shielding layer 30 may be formed by coating an external surface of the sealing portion 40 with a resin material including a conductive powder or forming a metal film on the external surface of the sealing portion 40. For example, the shielding layer 30 may be a metal film formed on the external surface of the sealing portion 40 using a sputtering method. However, the shielding layer 30 is not limited to this example, and various techniques such as a spray coating, a screen printing method, a vapor deposition method, an electrolytic plating method, an electroless plating method may be used to form the metal thin film.

The shielding layer 30 may also be disposed on an upper surface of the shielding wall 20 and may be electrically connected to the shielding wall 20.

The shielding wall 20 and the shielding layer 30 included in the shielding portion 70 may be formed using different manufacturing processes. Accordingly, the shielding wall 20 and the shielding layer 30 may be formed of different materials.

The electronic device module 100 may protect the electronic device 1 from an external environment and may also easily shield electromagnetic waves through the sealing portion 40 or the shielding portion 70.

Also, since the sealing portion 40 is disposed externally of the shielding wall 20, the shielding wall 20 may be prevented from being broken by external impact.

Further, since the shielding layer 30 is formed in a form of a thin film, a thickness of the shielding layer 30 may be reduced and, accordingly, an increase of a thickness of the electronic device module 100 caused by the shielding layer 30 may be reduced.

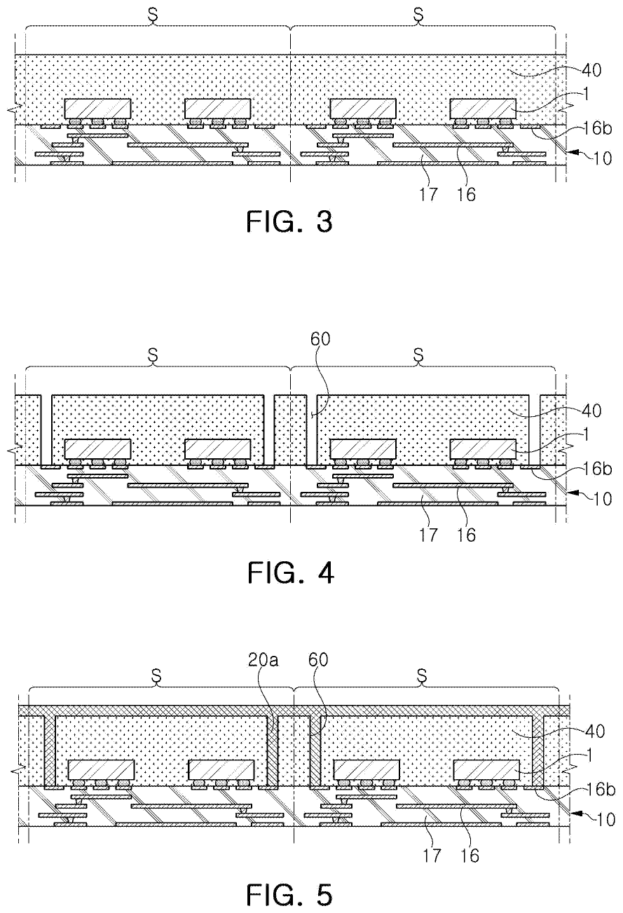

FIGS. 3 to 8 are diagrams illustrating a method of manufacturing the electronic device module 100, according to an embodiment.

As illustrated in FIG. 3, electronic devices 1 may be mounted on the first surface of a substrate 10.

The substrate 10 in the example embodiment may be a multilayer circuit substrate including a plurality of layers, and may include the plurality of wiring layers 16 electrically connected to each other, and at least a portion of the plurality of wiring layers 16 may be used as the ground electrode 16b.

The substrate 10 (hereinafter, a strip substrate) may have a form of a panel or a strip. The strip substrate 10 may be used to simultaneously manufacture a plurality of electronic device modules 100. A plurality of individual package regions S may be distinguished from one another on the strip substrate 10, and the plurality of the electronic device modules 100 may be simultaneously manufactured in the plurality of individual package regions S.

The electronic devices 1 may be adhered to the strip substrate 10 through a conductive adhesive such as solder.

Thereafter, the electronic devices 1 may be sealed by forming the sealing portion 40 on the first surface of the substrate 10.

Since the sealing portion 40 is formed on the first surface of the substrate 10, the sealing portion 40 may be configured to entirely embed the electronic devices 1.

In the process of forming the sealing portion 40, the sealing portion 40 may be manufactured using an insulating material such as an epoxy molding compound (EMC) through a transfer molding method, but is not limited to an EMC.

When the strip substrate 10 is used, the sealing portion 40 may be formed in an integrated form covering the individual package regions S of the strip substrate 10. However, as another example, multiple sealing portions 40 may be formed to be separated from each other in different individual package regions S.

As illustrated in FIG. 4, a trench 60 may be formed by partially removing the sealing portion 40.

The trench 60 may be formed by removing a portion of the sealing portion 40 along a position in which a ground electrode of the substrate 10 is disposed. A first surface of the strip substrate 10 may be externally exposed through the trench 60. Accordingly, a bottom surface of the trench 60 may be formed on the first surface of the strip substrate 10.

Also, the ground electrode 16a may be disposed on a bottom surface of the trench 60. Accordingly, when the trench 60 is formed, the ground electrode 16a may be externally exposed through the trench 60.

The trench 60 may be formed by partially removing the sealing portion 40 using a laser. The ground electrode 16a forming a bottom of the trench 60 may not be easily removed by the laser, since the ground electrode 16a is formed of a conductive material. Thus, only the sealing portion 40 may be removed by the laser, and the strip substrate 10 may not be removed.

Thereafter, as illustrated in FIG. 5, the shielding wall 20 may be formed by filling the trench 60 with a conductive material 20a and curing the conductive material. A conductive paste formed by adding a conductive filler to polymer material such as resin may be used as the conductive material 20a. The conductive filler may include a metal particle such as gold (Au), silver (Ag), copper (Cu), or nickel (Ni). However, the shielding wall is not limited to the foregoing materials and formation process.

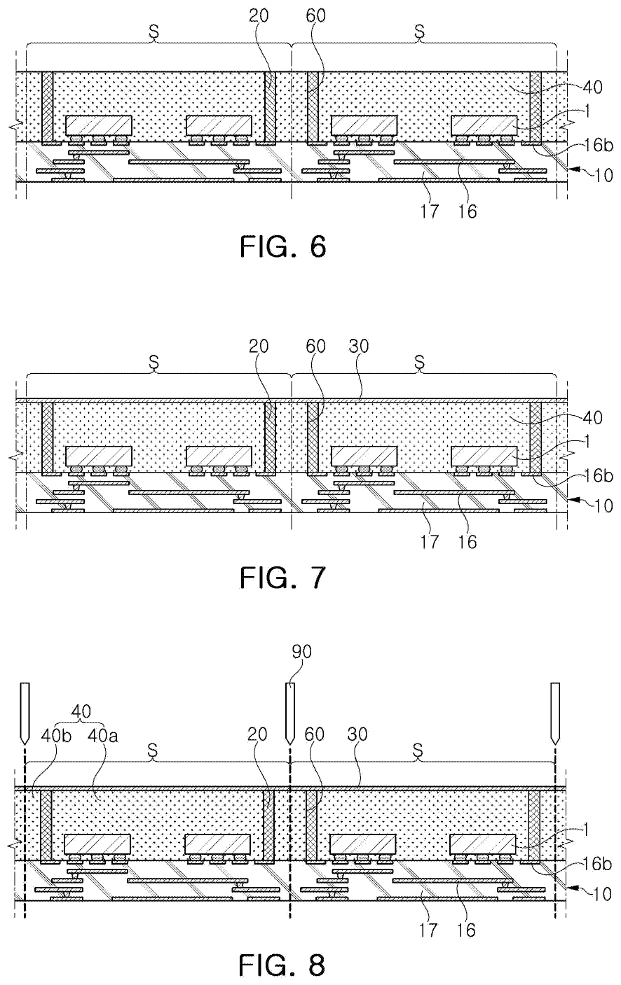

Once the shielding wall 20 is formed, a grinding process for removing an upper surface of the sealing portion 40 by a certain thickness and flattening the upper surface may be performed, as illustrated in FIG. 6. An upper end surface of the shielding wall 20 may be exposed externally of the sealing portion 40 through the grinding process, and the exposed surface (or the upper surface) of the shielding wall 20 exposed externally of the sealing portion 40 may be disposed on a same plane as the surface of the sealing portion 40 (the upper surface in FIG. 6).

As illustrated in FIG. 7, the shielding layer 30 may be formed along a surface formed by the sealing portion 40 and the shielding wall 20.

The shielding layer 30 may be formed by coating an external surface of the sealing portion 40 with a resin material including conductive filler, or forming a metal thin film on the external surface of the sealing portion 40. One of various techniques such as a sputtering method, a spray coating, a screen printing method, a vapor deposition method, an electrolytic plating method, or an electroless plating method may be used to form the metal thin film.

In the process of forming the shielding layer 30, the shielding layer 30 may also be disposed on a surface of the shielding wall 20 exposed externally of the sealing portion 40 and may thereby be electrically connected to the shielding wall 20.

The shielding wall 20 and the shielding layer 30 may be formed of different conductive materials (e.g., Cu, Ag, Au, Ni, Pt, Pd, or an alloy including any one or any combination of any two or more of Cu, Ag, Au, Ni, Pt, and Pd).

Thereafter, as illustrated in FIG. 8, the strip substrate 10 and the sealing portion 40 may be cut out, thereby completing the electronic device module 100.

For example, the cutting out of the strip substrate 10 and the sealing portion 40 may be performed by a blade 90.

The blade 90 may cut out the strip substrate 10 and the sealing portion 40 along a boundary of the individual package region S. In this example, the blade 90 may not be in contact with the shielding wall 20, and may cut out the sealing portion 40 disposed on boundary of the individual package region S. Accordingly, in the electronic device module which has been cut out, the shielding wall 20 may not be externally exposed, and the sealing portion 40 may be divided into an internal sealing portion 40a disposed in an internal space of the shielding wall 20 and an external sealing portion 40b disposed on an external side of the shielding wall 20.

The shielding wall 20 and a shielding layer 30 may be formed through separate processes.

If a shielding layer were to be formed together with a shielding wall, at a same time, using a conductive material for manufacturing the shielding wall it may be difficult to configure the shielding layer to have a reduced thickness. Thus, in such a case, a thickness of the electronic device module may increase due to the shielding layer.

However, when the shielding layer 30 is formed as a thin film through a separate process, as in the embodiment of FIGS. 3 to 8, a thickness of the electronic device module 100 may be reduced.

Also, an example in which the shielding wall is not provided and the shielding layer is also formed on a side surface of the sealing portion to replace the shielding wall is also possible. However, in such a case, the shielding layer may be easily expanded to the side surface of the substrate while the shielding layer is formed on the side surface of the sealing portion.

When the shielding layer is formed on the side surface of the substrate, the shielding layer may be in contact with the wiring layer exposed to the side surface of the substrate. Also, when an antenna is provided on the substrate, as in an embodiment described below, a shielding layer disposed on the side surface of the substrate may interfere with radiation of the antenna.

However, as described above, in the electronic device module 100, the shielding layer 30 may be only formed on an upper surface of the sealing portion 40 such that it may be difficult for the shielding layer 30 to expand to the side surface of the substrate 10. Thus, the issues described above may be prevented.

An electronic device module 100 may not be limited to the embodiment described above, and various applications and modifications of the electronic module 100 are possible.

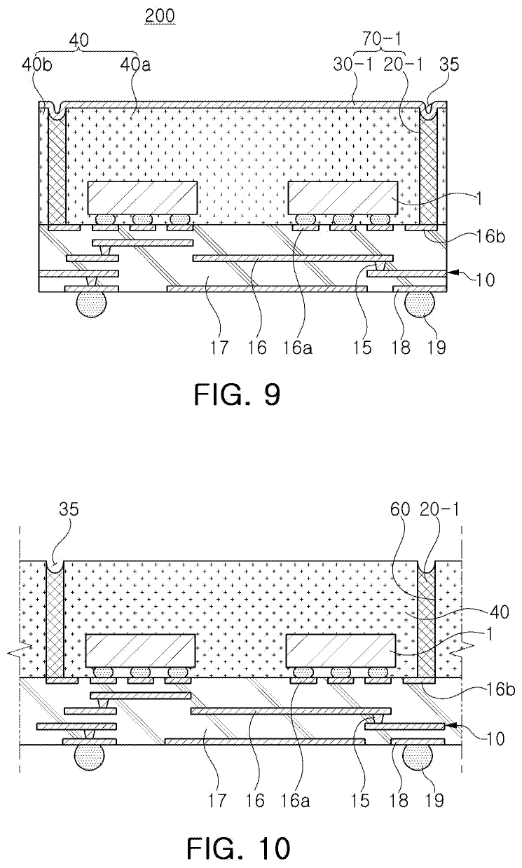

FIG. 9 is a cross-sectional diagram illustrating an electronic device module 200, according to an embodiment. FIG. 10 is a cross-sectional diagram illustrating a method of manufacturing the electronic device module 200.

Referring to FIG. 9, the electronic device module 200 may be configured similarly to the electronic device module 100, but may be different from the electronic device module 100 in that a groove 35 may be formed in a portion at which a shielding wall 20-1 and a shielding layer 30-1 of a shielding portion 70-1 are connected to each other.

As shown in FIG. 10, the electronic device module 200 may be manufactured by, after performing the process illustrated in FIG. 6 of the previously described manufacturing process, additionally performing the process of removing a portion of an upper portion of the shielding wall 20-1 before the shielding layer 30-1 is formed.

By partially removing the upper portion of the shielding wall 20-1, an upper surface of the shielding wall 20-1 may include the groove 35 having a concave form, and the shielding layer 30-1 may be disposed along an internal surface of the groove 35 formed on an upper surface of the shielding wall 20-1.

In the electronic device module 200, an adhesive area between the shielding wall 20-1 and the shielding layer 30-1 may be expanded as compared to the shielding wall 20 and the shielding layer 30 of the electronic device module 100. Accordingly, adhesive reliability between the shielding wall 20-1 and the shielding layer 30-1 may be improved.

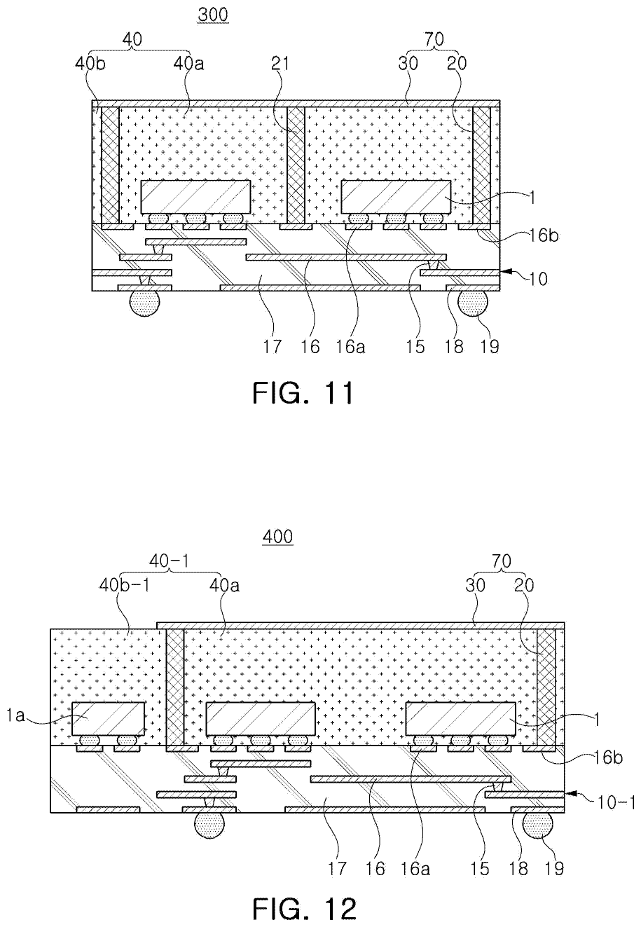

FIG. 11 is a cross-sectional diagram illustrating an electronic device module 300, according to an embodiment.

Referring to FIG. 11, the electronic device module 300 may include a shielding barrier wall 21 disposed in an internal region within the shielding wall 20, and disposed between electronic devices 1.

The shielding barrier wall 21 may be connected to the shielding wall 20. For example, the shielding barrier wall 21 may be integrated with the shielding wall 20.

The shielding barrier wall 21 may be formed using the same method used to form the shielding wall 20. Accordingly, the shielding barrier wall 21 may be formed of a material the same as a material of the shielding wall 20, and may have a shape similar to a shape of the shielding wall 20.

When the shielding barrier wall 21 is included, propagation of electromagnetic waves between the electronic devices 1 may be blocked. Accordingly, electromagnetic interference between the electronic devices 1 may be prevented.

The shielding barrier wall 21 may be modified to have various forms. In the example, the shielding barrier wall 21 may divide the internal space of the shielding wall 20 into at least two spaces. However, the shielding barrier wall 21 is not limited to such a configuration, and as long as electromagnetic interference between the electronic devices 1 may be blocked, the shielding barrier wall 21 may be disposed in various forms.

FIG. 12 is a cross-sectional diagram illustrating an electronic device module 400, according to another embodiment.

Referring to FIG. 12, a shielding layer 30 may be disposed only on a portion of one surface of an electronic device module 400, rather than an entirety of one surface.

In the example embodiment, the shielding layer 30 may only be disposed on the internal sealing portion 40a of a sealing portion 40-1, and may not be disposed or may be partially disposed on an external sealing portion 40b-1 of the sealing portion 40-1. Accordingly, at least a portion of one surface of the external sealing portion 40b-1 may be exposed externally of the shielding layer 30. However, the external shielding portion 40b-1 is not limited to such a configuration, and the external sealing portion 40b-1 may be partially disposed on the internal sealing portion 40a.

The electronic device module 400 may be manufactured by, after the process illustrated in FIG. 6 is performed, disposing a mask on a surface of the external sealing portion 40b-1 and forming the shielding layer 30. Alternatively, the electronic device module 400 may be manufactured by, after the process illustrated in FIG. 7 is performed, removing the portion of the shielding layer 30 formed on a surface of the external sealing portion 40b-1 by a method such as an etching method, or the like.

As least one communication device 1a may be disposed in the external sealing portion 40b-1. In the example embodiment, the communication device 1a may be a chip-type antenna device mounted on a substrate 10-1 along with the electronic component 1. However, the communication device 1a is not limited to this example.

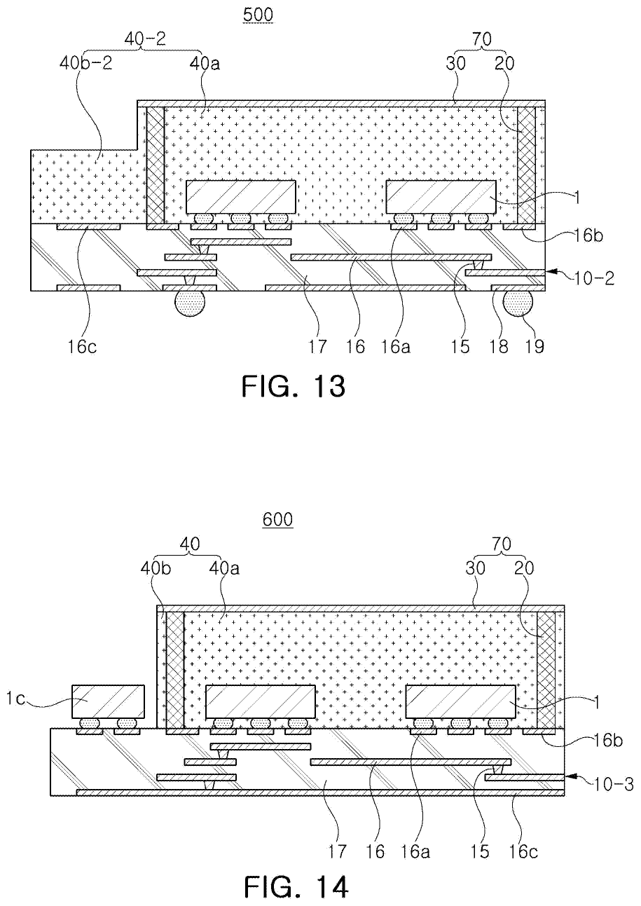

FIG. 13 is a cross-sectional diagram illustrating an electronic device module 500, according to an embodiment.

Referring to FIG. 13, an electronic device module 500 in the example embodiment may be configured similarly to the electronic device module 400 illustrated in FIG. 12, but a thickness of an external sealing portion 40b-2 of a sealing portion 40-2 may be different.

The electronic device module i500 may be manufactured by, after the process illustrated in FIG. 7 is performed, partially removing the external sealing portion 40b-2 by a grinding method. Accordingly, at least a portion of the external sealing portion 40b-2 may have a thickness less than that of the internal sealing portion 40a.

An antenna 16c having a circuit wiring form may be provided in the external sealing portion 40b-2. The antenna 16c may be disposed on the first surface of a substrate 10-2 along with the electronic device 1, but is not limited to such a configuration. The antenna 16c may be modified to have various forms. For example, the antenna 16c may be an antenna having a circuit wiring form and formed on a surface of the external sealing portion 40b-1.

In the electronic device modules 400 and 500 illustrated in FIGS. 12 and 13, respectively, electrical waves may not be blocked by the shielding layer 30 even when a communication device such as an antenna is buried in the external sealing portion 40b-1 or 40b-2. Accordingly, the device 1 to or from which electromagnetic waves need to be blocked, and the communication device 1a and the antenna 16c, which need to radiate electrical waves, may be disposed together in a single module.

FIG. 14 is a cross-sectional diagram illustrating an electronic device module 600, according to an embodiment.

Referring to FIG. 14, in the electronic device module 600, the sealing portion 40 may be disposed only on a portion of the first surface of a substrate 10-3. Also, the connection component 1c may be disposed externally of the sealing portion 40.

The connection component 1c may be a connector to which an FPCB or a cable is connected. Accordingly, the electronic device module 600 may be electrically connected to an external structure or device through the connection component 1c.

Also, in the electronic device module 600, an antenna 16c may be provided on one surface (e.g., the second surface) of the substrate 10.

The antenna 16c may be formed in a circuit wiring form. Accordingly, a portion of a wiring layer 16 of the substrate 10-3 may be used as an antenna. For example, the antenna 16c may be disposed on the second surface of the substrate 10-3, or may be disposed in the substrate 10-3 and disposed on the wiring layer 16 adjacent to the second surface of the substrate 10-3.

Since the electronic device module in the example embodiment may be electrically connected to an external structure or device through the connection component 1c, the entire second surface of the substrate 10-3 may be used as an antenna area. Accordingly, a size of the antenna may be expanded, and accordingly, radiation efficiency of the antenna may increase.

In the example, the antenna 16c may be configured in a circuit wiring form. However, the antenna 16c is not limited to a circuit wiring form, and may be modified to have various forms. For example, the antenna 16c may be a device type antenna mountable on the substrate 10-3, such as a chip antenna, and may be mounted on the second surface of the substrate 10-3.

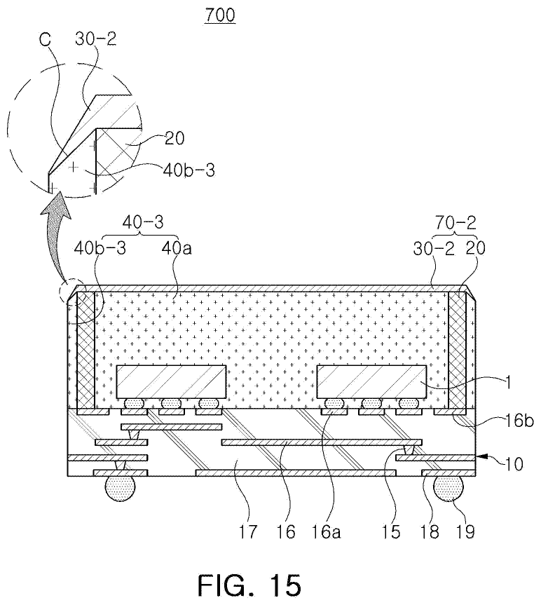

FIG. 15 is a cross-sectional diagram illustrating an electronic device module 700, according to an embodiment.

Referring to FIG. 15, in the electronic device module 700, an edge of an upper surface of a sealing portion 40-3 may be chamfered to form a chamfered surface C. More specifically, the chamfered surface C may be formed on an upper surface of an external sealing portion 40b-3. Additionally, a shielding layer 30-2 of a shielding portion 70-2 may also be disposed on the chamfered surface C (hereinafter, a chamfer portion C).

The shielding layer 30-2 may be formed through a sputtering method. In this case, the greater the distance from a sputtering target, the more the thickness of the shielding layer 30-2 may decrease.

In the sputtering process, a sputtering target may be disposed on an upper portion of the sealing portion 40-3/external sealing portion 40b-3. Accordingly, when the chamfer portion C is formed on an edge of the sealing portion 40-3, a thickness of the shielding layer 30-2 disposed on the chamfer portion C may be less than that of the remaining portion of the shielding layer 30-2 (e.g., a portion of the shielding layer 30-2 disposed on the upper surface of the internal sealing portion 40a and the shielding wall 20). Also, for the similar reason, the portion of the shielding layer 30-2 formed on the chamfer portion C may have a thickness decreasing toward an edge of the electronic device module 700.

In the electronic device module 700, a thickness of the shielding layer 30-2 may be reduced on a cut out surface, cut out by the blade 90 (FIG. 8).

When a thickness of the shielding layer 30-2 is great, a portion of the shielding layer 30-2 may be peeled from the sealing portion 40-3 by the blade 90 in the cutting out process illustrated in FIG. 8, or a burr may occur on the cut-out surface of the shielding layer 30-2.

However, because a thickness of the shielding layer 30-2 is reduced in the electronic device module 700, the issues described above may be reduced.

The chamfer portion C may be arranged by forming a V-shaped groove on the sealing portion 40-3 along a boundary of an individual package region S after the process illustrated in FIG. 6 is completed. However, a process of forming the chamfer portion C is not limited to this example.

An electronic device module according to the disclosure herein may protect an electronic device mounted on a substrate from an external environment through a sealing portion or a shielding portion, and may also effectively shield electromagnetic waves.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. In addition, respective embodiments may be combined with each other. For example, the pressing members disclosed in the above-described embodiments may be used in combination with each other in one force sensing device. Therefore, the scope of the disclosure is defined not by the detailed description, but by the claims and their equivalents, and all variations within the scope of the claims and their equivalents are to be construed as being included in the disclosure.

What is claimed is:

1. An electronic device module, comprising:
a substrate;
at least one electronic device mounted on a first surface of the substrate;
a shielding wall mounted on the first surface of the substrate;
a sealing portion disposed on the first surface of the substrate such that the at least one electronic device and the shielding wall are embedded in the sealing portion; and
a shielding layer disposed on one surface of the sealing portion,
wherein at least a portion of the sealing portion is disposed externally of the shielding wall, and
wherein the shielding wall and the shielding layer are formed of different materials.

2. The electronic device module of claim 1, wherein the shielding wall is disposed to surround the at least one electronic device, and at least a portion of an end of the shielding wall is electrically connected to the shielding layer.

3. The electronic device module of claim 2, further comprising:
a shielding barrier wall disposed in an internal region inside of the shielding wall, and disposed between electronic devices among the at least one electronic device.

4. The electronic device module of claim 2, wherein the sealing portion comprises an internal sealing portion disposed in an internal space inside of the shielding wall, and an external sealing portion disposed on an external side of the shielding wall.

5. The electronic device module of claim 4, wherein at least a portion of one surface of the external sealing portion is exposed externally of the shielding layer.

6. The electronic device module of claim 4, wherein at least a portion of the external sealing portion has a thickness less than a thickness of the internal sealing portion.

7. The electronic device module of claim 4, further comprising at least one communication device disposed in the external sealing portion.

8. The electronic device module of claim 2,
wherein the shielding wall is formed of a polymer material containing conductive filler, and
wherein the shielding layer is formed of a metal material.

9. The electronic device module of claim 1, wherein an interfacial surface between the shielding wall and the shielding layer is coplanar with an interfacial surface between the sealing portion and the shielding layer.

10. The electronic device module of claim 1, wherein an upper surface of the shielding wall includes a groove in contact with the shielding layer.

11. The electronic device module of claim 1, further comprising:
an antenna disposed on a second surface of the substrate.

12. The electronic device module of claim 1, wherein one surface of the sealing portion includes a chamfer portion chamfered along an edge.

13. The electronic device module of claim 12, wherein a portion of the shielding layer disposed on the chamfer portion has a thickness decreasing toward the edge.

14. A method of manufacturing an electronic device module, the method comprising:
forming a sealing portion embedding at least one electronic device on a substrate;
forming a trench by partially removing the sealing portion;
forming a shielding wall by filling the trench with a conductive member; and
forming a shielding layer on an upper surface of the sealing portion,
wherein the shielding wall is not exposed externally of the sealing portion, and
wherein the shielding wall is formed of a material different from a material of the shielding layer.

15. The method of claim 14, further comprising forming a groove on an end of the shielding wall after the forming of the shielding wall.

16. The method of claim 14, wherein the sealing portion comprises an internal sealing portion disposed in an internal space formed inside of the shielding wall and an external sealing portion disposed on an external side of the shielding wall.

17. The method of claim 16, wherein the at least one electronic device is disposed in the internal sealing portion.

18. The method of claim 16, wherein at least a portion of the external sealing portion has a thickness less than a thickness of the internal sealing portion, and
wherein an antenna device is disposed in the external sealing portion or at an interface between the substrate and the external sealing portion.
